(19) United States
(12) Patent Application Publication
(10) Pub. No.: US 2017/0062634 A1
(43) Pub. Date: Mar. 2, 2017

(54) Method to Condition an Annealing Tool for High Quality CuZnSnS(Se) Films to Achieve High Performance Solar Cells Reliably

(71) Applicant: International Business Machines Corporation, Armonk, NY (US)

(72) Inventors: Yu Luo, Hopewell Junction, NY (US); David B. Mitzi, Hillsborough, NC (US); Sean M. Seefeld, San Jose, CA (US); Xiaoyan Shao, Yorktown Heights, NY (US); Sathish Thiruvengadam, Ballston Lake, NY (US)

(21) Appl. No.: 14/835,295

(22) Filed: Aug. 25, 2015

(51) Int. Cl. H01L 31/032; H01L 31/0216; H01L 31/18

(52) U.S. Cl. CPC H01L 31/0326; H01L 31/18; H01L 31/1864; H01L 31/02168

(57) ABSTRACT

Techniques for improved kesterite film production through annealing chamber conditioning to achieve solar cells with a power conversion efficiency of greater than 12% are provided. In one aspect, a method of conditioning an annealing chamber for forming a kesterite film is provided. The method includes the step of: coating one or more inner surfaces of the annealing chamber with a film containing Sn and at least one of S and Se. A method for forming a kesterite film, a method for forming a solar cell, and a solar cell are also provided.

### FIELD OF THE INVENTION

The present invention relates to kesterite film production, and more particularly, to techniques for improved kesterite film production through annealing chamber conditioning to achieve solar cells with a power conversion efficiency of greater than 12%.

### BACKGROUND OF THE INVENTION

CuZnSnSₓ(Se)₁₋ₓ thin film solar cells have the potential to become the most cost effective means for producing solar energy due to their low cost materials and earth-abundant elements in the film. The performance of these solar cells depends highly on the quality of the CuZnSnSₓ(Se)₁₋ₓ absorber layer. The annealing process used in forming CuZnSnSₓ(Se)₁₋ₓ films from various precursors has been found to be an important component in achieving the best performance.

To date, efforts to increase CuZnSnSx(Se)₁₋ₓ thin film solar cell efficiency have focused on factors such as precursor formulation, annealing time and temperature, and the amount of S or Se sources used. See, for example, Ahmed et al., “A High Efficiency Electrodeposited Cu₂ZnSnS₄ Solar Cell,” Adv. Energy Mater., pgs. 1-7 (November 2011) (annealing a CuZnSn precursor in a S environment); and Todorov et al. “Beyond 11% Efficiency: Characteristics of State-of-the-Art Cu₂ZnSn(S,Se)₄ Solar Cells,” Adv. Energy Mater., pgs. 1-5 (August, 2012) (varying the concentration of S in the atmosphere during the final heat treatment to control the band gap in the resulting film).

While devices with power conversion efficiencies of as high as 11% have, on occasion, been produced using conventional processes, this result is not typical or reproducible for high volume production. Thus, techniques for consistently producing high power conversion efficiency CuZnSnSₓ(Se)₁₋ₓ thin film solar cells would be desirable.

### SUMMARY OF THE INVENTION

The present invention provides techniques for improved kesterite film production through annealing chamber conditioning to achieve solar cells with a power conversion efficiency of greater than 12%. In one aspect of the invention, a method of conditioning an annealing chamber for forming a kesterite film is provided. The method includes the step of: coating one or more inner surfaces of the annealing chamber with a film containing Sn and at least one of S and Se.

In another aspect of the invention, a method for forming a kesterite film is provided. The method includes the steps of: coating one or more inner surfaces of an annealing chamber with a film containing Sn and at least one of S and Se; and heating a precursor film on a substrate within the annealing chamber to form the kesterite film on the substrate.

In yet another aspect of the invention, a method for forming a solar cell is provided. The method includes the steps of: coating one or more inner surfaces of an annealing chamber with a film containing Sn and at least one of S and Se; heating a precursor film on a substrate within the annealing chamber to form a kesterite absorber on the substrate; forming an n-type semiconductor on the kesterite absorber; and forming a top electrode on the n-type semiconductor.

In still yet another aspect of the invention, a solar cell is provided. The solar cell includes: a substrate; a bottom electrode on the substrate; a kesterite absorber on the bottom electrode, wherein the kesterite absorber comprises a kesterite film formed according to the present method; an n-type semiconductor on the kesterite absorber; an antireflection coating on the n-type semiconductor; and a top electrode on the antireflection coating.

A more complete understanding of the present invention, as well as further features and advantages of the present invention, will be obtained by reference to the following detailed description and drawings.

### BRIEF DESCRIPTION OF THE DRAWINGS

FIG. 1 is a diagram illustrating an exemplary methodology for forming a kesterite absorber material according to an embodiment of the present invention;

FIG. 2 is a diagram illustrating one exemplary methodology for conditioning the annealing chamber according to an embodiment of the present invention;

FIG. 3 is a diagram illustrating another exemplary methodology for conditioning the annealing chamber according to an embodiment of the present invention;

FIG. 4 is a cross-sectional diagram illustrating a starting platform for fabricating a solar cell which includes a substrate coated with a layer of electrically conductive material according to an embodiment of the present invention;

FIG. 5 is a cross-sectional diagram illustrating the method of FIG. 1 having been used to form a kesterite absorber on the substrate according to an embodiment of the present invention;

FIG. 6 is a cross-sectional diagram illustrating an n-type semiconductor having been formed on the kesterite absorber and an antireflection coating having been formed on the n-type semiconductor layer according to an embodiment of the present invention;

FIG. 7 is a cross-sectional diagram illustrating a top electrode having been formed on the antireflection coating according to an embodiment of the present invention; and

FIG. 8 is a diagram illustrating an exemplary set-up for conditioning an annealing chamber which in this example is a quartz lid according to an embodiment of the present invention.

### DETAILED DESCRIPTION OF PREFERRED EMBODIMENTS

Advantageously, it has been discovered herein that by conditioning the annealing chamber (or a surface of the annealing chamber facing the thin film surface) high quality CuZnSnSₓ(Se)ᵢ₋ₓ films can be produced for devices having power conversion efficiencies exceeding 12%. The present techniques can be used to quickly and effectively condition the annealing tool to reach optimum condition for best quality CuZnSnSₓ(Se)₁₋ₓ films.

An exemplary embodiment of the present techniques is now described by way of reference to methodology 100 of FIG. 1 for forming a CuZnSnSₓ(Se)₁₋ₓ material. The kesterite material CuZnSnSₓ(Se)₁₋ₓ (also commonly abbreviated as “CZTS/Se”) includes copper (Cu), zinc (Zn), tin (Sn), and at least one of sulfur (S) and selenium (Se). As will be described in detail below, CuZnSnSₓ(Se)₁₋ₓ is used as an absorber material in the present solar cells. Further, the designation “S/Se” is used herein to indicate the presence of at least one of S and Se, e.g., S/Se indicates the presence of S (and no Se), Se (and no S), or a combination of S and Se.

In general, the present techniques involve first conditioning a chamber, and then annealing precursor samples in the conditioned chamber (in the presence of S and/or Se) to form the final film. The term “precursor,” as used herein, refers to the fact that the final composition and/or distribution of elements throughout the kesterite film will be established only after the anneal has been performed.

In step 102, the annealing chamber is cleaned to remove contaminants from the chamber. Any suitable chemical, physical, or high temperature annealing methods known in the art may be used to clean the chamber. By way of example only, an SCl cleaning solution can be used containing 5:1:1 parts of water (H₂O), ammonium hydroxide (NH₄OH), and hydrogen peroxide (H₂O₂), respectively.

In step 104, the annealing chamber is conditioned. Generally, this conditioning involves coating one or more inner surfaces of the annealing chamber with a film containing Sn and at least one of S and Se. The conditioned chamber will then be used in step 106 to process kesterite film samples. Thus, it is preferable that this ‘conditioning’ film is formed on at least the surface(s) of the chamber facing the kesterite film samples. Further, once conditioned, the annealing chamber can be used to process multiple samples before re-conditioning is needed. To use a simple example, the annealing chamber might be just a quartz lid placed over a quartz plate on a hot plate. See below. In that case, the present techniques can be employed to condition a quartz lid, which can then be used in multiple ‘annealing chamber’ set-ups to process samples. Namely, conditioning the quartz lid alone is sufficient to attain the beneficial effects described herein.

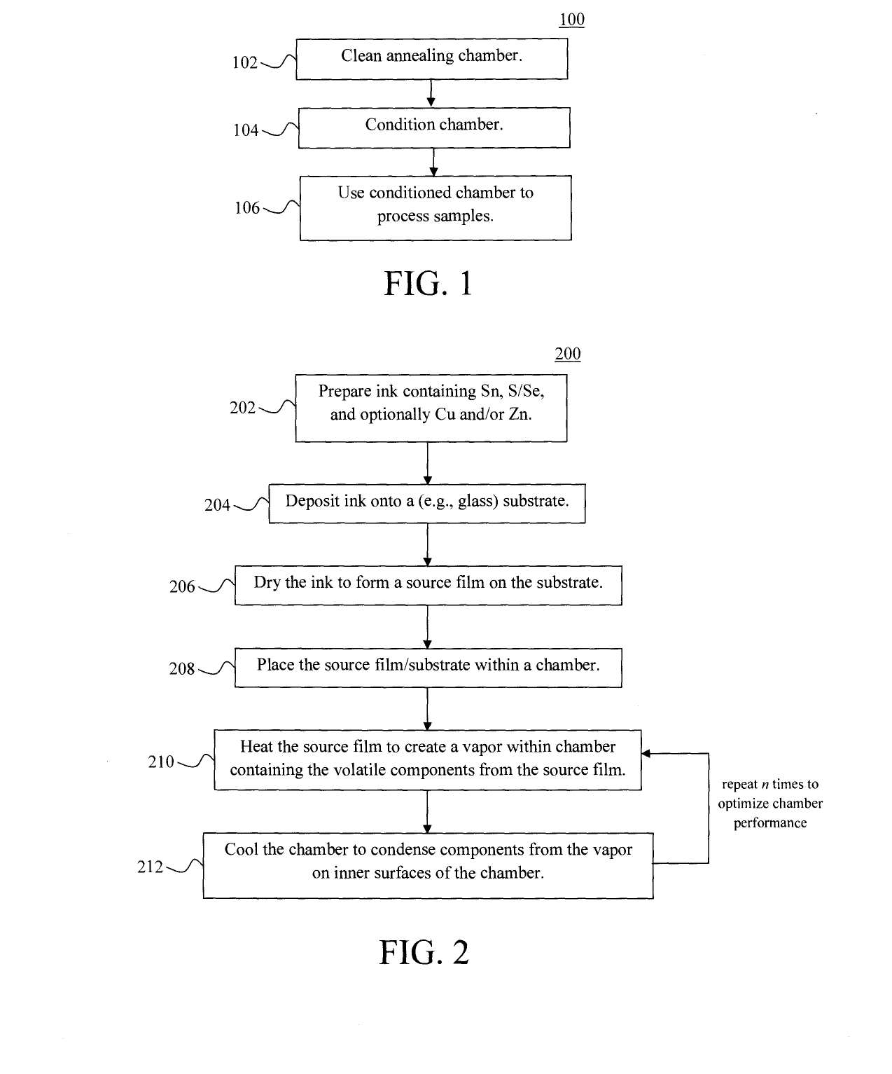

The annealing chamber can be conditioned in number of different ways. For instance, one scenario involves annealing a substrate (e.g., a glass substrate) coated with a source film containing Sn and at least one of S and Se within the chamber to form a vapor. Upon cooling, these volatile components will condense on the inner surfaces of the chamber forming a film of Sn, and S/Se. Optionally, the source film can also contain Cu and Zn. While Cu and Zn are non-volatile components of the source film and thus will not be present on the surface(s) of the chamber, Cu and Zn form compounds with Sn, S, and Se, and thus may play a role in maintaining vapor pressure and relative ratios of the volatile species. This exemplary embodiment for conditioning the chamber is illustrated in FIG. 2.

Referring briefly to FIG. 2, an exemplary methodology 200 is provided for conditioning the annealing chamber in accordance with the present techniques. In step 202, an ink is prepared containing Sn, S/Se, and optionally Cu and/or Zn dissolved or dispersed in a liquid medium, such as hydrazine or a hydrazine-water mixture, with a hydrazine content of from about 0.1% to about 99.9%, and ranges therebetween. By way of example only, the ink can be prepared using the techniques described in U.S. Patent Application Publication Number 2011/0094557 by Mitzi et al., entitled “Method of Forming Semiconductor Film and Photovoltaic Device Including the Film” (hereinafter “U.S. Patent Application Publication Number 2011/0094557”) and U.S. Patent Application Publication Number 2011/0097496 by Mitzi et al., entitled “Aqueous-Based Method of Forming Semiconductor Film and Photovoltaic Device Including the Film” (hereinafter “U.S. Patent Application Publication Number 2011/0097496”), the entire contents of each of which are incorporated by reference as if fully set forth herein. For instance, as described in U.S. Patent Application Publication No. 2011/0094557 A1 and U.S. Patent Application Publication Number 2011/0097496 A1, a solution A is prepared containing hydrazine, Cu and at least one of S and Se (depending on the desired final composition), a dispersion B is prepared containing hydrazine, Sn, Zn and at least one of S and Se (depending on the desired final composition), and the components A and B are then mixed together to form the ink. According to an exemplary embodiment, the ink is prepared in hydrazine and contains: Se in a concentration of from about 2 moles/liter (mol/L) to about 4 mol/L, and ranges therebetween, S in a concentration of from about 1 mol/L to about 1.5 mol/L, and ranges therebetween, Sn in a concentration of from about 0.5 mol/L to about 0.7 mol/L, and ranges therebetween, Cu in a concentration of from about 0.8 mol/L to about 0.9 mol/L, and ranges therebetween, and a Zn concentration of from about 0.5 mol/L to about 0.7 mol/L, and ranges therebetween. By way of example only, the atomic ratio of Cu/Sn is from about 1.2 to about 1.8, and ranges therebetween, the atomic ratio of Zn/Sn is from about 0.9 to about 1.2, and ranges therebetween, and the atomic ratio of Cu/ZnSn is from about 0.65 to about 0.9, and ranges therebetween.

In step 204, the ink is deposited onto a substrate. A suitable substrate includes, but is not limited to, a glass substrate. The ink may be deposited onto the substrate using a solution-based deposition process, such as spin coating, dip coating, doctor blading, curtain coating, slide coating, spraying, slit casting, meniscus coating, screen printing, ink jet printing, pad printing, flexography, and gravure printing.

In step 206, the ink deposited on the substrate is dried at a temperature of from about 50° C. to about 150° C., and ranges therebetween, to form a source film on the substrate. The source film contains Sn and at least one of S and Se. As provided above, Cu and/or Zn may also be included in the ink/source film. In that case, slightly higher temperatures (e.g., from about 400° C. to about 480° C., and ranges therebetween) may be employed in step 206 in order to form the source film containing CuZnSnSₓ(Se)₁₋ₓ crystals and secondary phases such as ZnS, ZnSe, CuS, CuSe, SnS, SnSe, etc.

The substrate with the source film is then used to condition the annealing chamber. Namely, in step 208 the film/substrate is placed in the annealing chamber, and in step 210 the film/substrate is heated to create a vapor within the annealing chamber containing the volatile components (i.e., Sn, S, and Se) from the source film. In step 212, the heat is turned off and the annealing chamber is permitted to cool back down to room temperature. This cooling will cause the vapor components to condense on and coat the surfaces of the chamber. According to an exemplary embodiment, once the source film/substrate has been placed in the annealing chamber (as per step 208), the temperature in the chamber is slowly raised (e.g., at a ramping rate of less than 120° C. per minute) until the temperature in the chamber is from about 570° C. to about 650° C., and ranges therebetween (as per step 210). The chamber is held at this temperature for a duration of from about 10 minutes to about 15 minutes and ranges therebetween, after which time the heat is turned off and the chamber is allowed to cool to room temperature, i.e., from about 20° C. to about 26° C. and ranges therebetween (as per step 212). By way of the heating, the volatile components of the source film will form a vapor in the chamber which will condense on and coat the surfaces of the chamber upon cooling. The coating will contain Sn and S/Se (depending on the content of the source film).

As shown in FIG. 2, the conditioning process may be repeated multiple times (i.e., n times) to condition the chamber into its peak performance. This can be accomplished simply by repeating the heating and cooling steps (i.e., steps 210-212) n times without removing the source film/substrate from the chamber. According to an exemplary embodiment, n=1-10, e.g., n=5−10.

It has been found herein that the amount of conditioning changes the thickness of the coating on the chamber, which has some kind of threshold that, once passed, the chamber is good to use for processing/producing high efficiency samples. As provided above, e.g., the number of minimum repeats to achieve peak performance of the chamber through conditioning is between 5-10 times. To quantify the chamber conditioning, it is simply a matter of making the film into solar cells and then measuring the performance. Once a conditioned chamber has reached peak performance, it can be used repeatedly for many samples, e.g., on the order of a few months worth of processing during which time about a few hundreds of substrates can be processed.

Advantageously, by way of the present techniques, the same source film (formed in steps 202-206) may be used to treat multiple chambers. Namely, the source film/substrate may be placed in a first chamber, the above-described heat ramping-up and cooling process can be performed to condition the chamber, the source film/substrate can then be transferred to a second chamber and the conditioning process can be repeated.

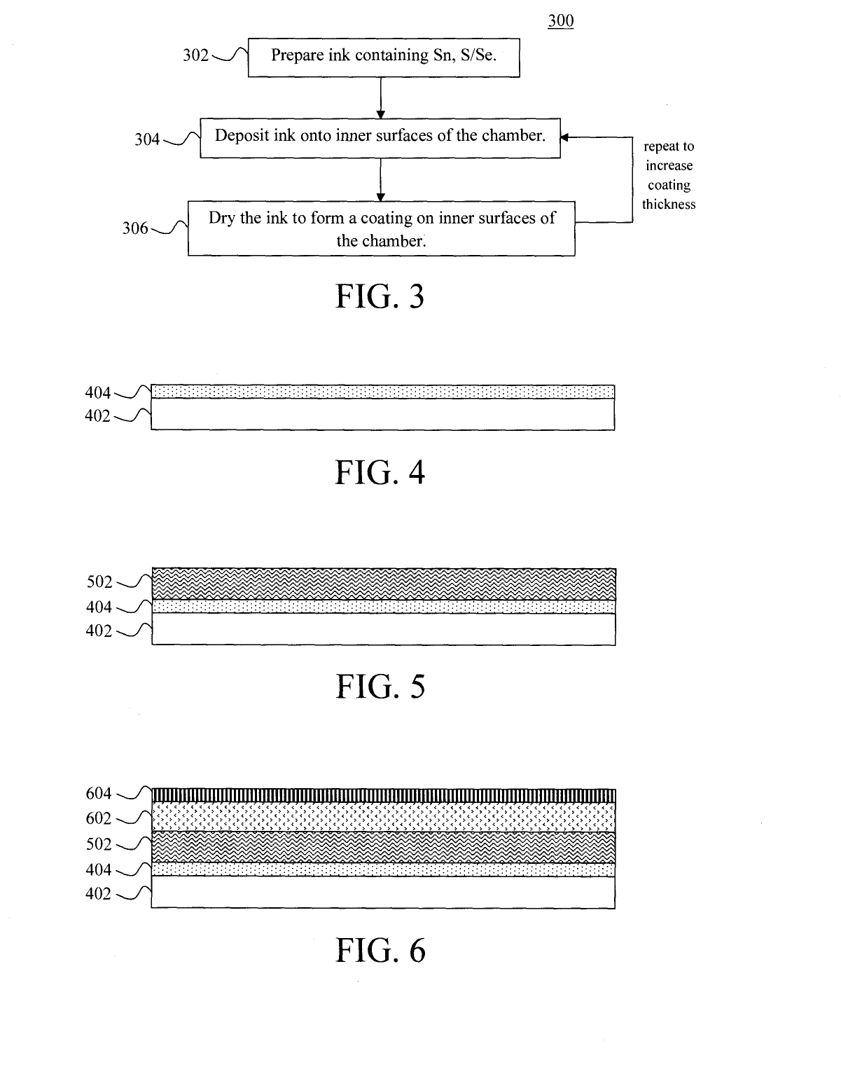

Another process anticipated herein for conditioning the chamber involves directly depositing the ink onto the inner surfaces of the chamber. See methodology 300 of FIG. 3 for conditioning the annealing chamber in accordance with an alternative embodiment of the present techniques. In step 302, an ink is prepared. As described in detail above, the ink may be formed by dissolving or dispersing Sn and S/Se in a liquid medium, such as hydrazine or a hydrazine-water mixture. In this case, however, one might not choose to include Cu or Zn in the ink formulations. Namely, as provided above, Cu and Zn can be included in the source film to help control the vapor pressure when the source film is heated/cooled to condition the chamber. However, Cu and Zn are generally not volatile under these conditions, and will not be present in the conditioning film formed on the surfaces of the chamber. Thus when directly applying the ink to the chamber surfaces (e.g., via solution-based deposition) as is done in the present embodiment, vapor pressure is not a consideration, and thus Cu and Zn may not be included in the formulation.

In step 304, the ink is deposited onto the inner surfaces of the chamber. The ink may be deposited onto the substrate using a solution-based deposition process, such as spin coating, dip coating, doctor blading, curtain coating, slide coating, spraying, slit casting, meniscus coating, screen printing, ink jet printing, pad printing, flexography, and gravure printing. Next, in step 306, the ink is dried at a temperature of from about 50° C. to about 150° C., and ranges therebetween, to form a coating on the inner surfaces of the chamber containing Sn and at least one of S and Se (depending on the composition of the ink). As shown in FIG. 3, the process can be repeated to deposit multiple layers of the coating, with a drying step in between, to increase the thickness of the coating on the chamber.

Other techniques are also anticipated herein for conditioning the chamber. For example, sputtering, evaporation (e.g., via thermal heating or electron beam (e-beam)), etc. can be used to deposit a coating on the inner surfaces of the chamber from a source material(s).

Referring back to FIG. 1, in step 106 the conditioned chamber can then be used to process samples. For instance, according to an exemplary embodiment described below, the conditioned chamber is used to anneal CuZnSnSₓ(Se)₁₋ₓ precursors with added S and/or Se to form a kesterite absorber film, e.g., for a kesterite solar cell.

According to an exemplary embodiment, the present techniques are implemented in the fabrication of a kesterite-based solar cell. See, for example, FIGS. 4-7. As shown in FIG. 4, the process begins with substrate 402. Suitable substrates include, but are not limited to, metal foil substrates, glass substrates, ceramic substrates, polymer substrates, and any combination thereof. The substrate is preferably coated with a layer of electrically conductive material which can serve as a back contact (i.e., bottom electrode) of the solar cell. See, for example, FIG. 4, where the substrate 402 is coated with a layer 404 of conductive material. By way of example only, the layer of conductive material 404 can be formed from molybdenum that is deposited onto the substrate 402 using a process such as sputtering or evaporation.

A kesterite absorber 502 is then formed on the layer 404 of conductive material. See FIG. 5. According to an exemplary embodiment, the kesterite absorber 502 is formed on the substrate 402 in accordance with methodology 100 of FIG. 1. As described in detail above, this involves first conditioning the annealing chamber. Suitable chamber conditioning techniques were described in accordance with the description of FIGS. 2 and 3, above. Advantageously, once conditioned the same chamber can be used to process multiple samples before it needs to be cleaned and re-conditioned. For instance, as provided above, the same conditioned chamber can be used for a few months worth of processing during which time about a few hundreds of substrates can be processed.

According to an exemplary embodiment, the kesterite absorber 502 has the formula CuZnSnSₓ(Se)₁₋ₓ wherein 0≦×≦1. To form the kesterite absorber 502, a precursor film is formed on the layer 404 of conductive material, and the substrate/precursor film is heated in the conditioned chamber to form the kesterite absorber 502. As highlighted above, the term “precursor” implies that the final composition and/or distribution of elements throughout the kesterite film will be established only after the anneal in the conditioned chamber has been performed. More specifically, the composition of the precursor film may be outside of the compositional range for the kesterite phase. A kesterite phase implies a certain crystal structure, which is stable only over a limited range of Cu—Zn—Sn—S—Se stoichiometry and heat treatment conditions. Alternatively, the precursor film may already have the correct stoichiometry to yield the kesterite phase, however the precursor film might not yet have an optimal composition within the kesterite phase for high performance. The annealing in the conditioned chamber serves to improve the clarity of the film, the film composition, grain structure, and/or homogeneity.

According to an exemplary embodiment, the precursor film for forming the kesterite absorber 502 contains Cu, Zn, Sn, and preferably at least one of S and Se. With regard to S/Se, a source (i.e., other than the precursor film) may optionally be employed during the anneal to provide S/Se for the final film composition and/or to replace these volatile components lost from the precursor film during the anneal. See below. The precursor film may be formed on the substrate 402/layer 404 of conductive material in a number of different ways. For example, the precursor film may be deposited from an ink containing a mixture of these elements. Namely, in the same manner as described in accordance with the description of FIGS. 2 and 3 above, an ink can be prepared containing Cu, Zn, Sn, and preferably at least one of S and Se dissolved or dispersed in a liquid medium, such as hydrazine or a hydrazine-water mixture, with a hydrazine content of from about 0.1% to about 99.9%, and ranges therebetween. The components of the ink can be introduced into the ink in their elemental form (i.e., Cu, Zn, Sn, S, Se), as binary metal chalcogenides such as Cu₂S, Cu₂Se, Cu₂(S,Se), SnS, SnSe, Sn(S,Se), SnS₂, SnSe₂, Sn(S,Se)₂, ZnS, ZnSe, Zn(S,Se), ternary metal chalcogenides such as Cu₂SnS₃, Cu₂SnSe₃, Cu₂Sn(S,Se)₃, quaternary metal chalcogenides such as Cu₂ZnSnS₄, Cu₂ZnSnSe₄ and Cu₂ZnSn(S,Se)₄, and combinations including at least one of the foregoing elements/metal chalcogenides. The ink can be cast onto the layer 404 of conductive material and then subsequently dried to form the precursor layer on the layer 404 of conductive material. The ink may be cast onto the layer 404 of conductive material using a solution-based deposition process, such as spin coating, dip coating, doctor blading, curtain coating, slide coating, spraying, slit casting, meniscus coating, screen printing, ink jet printing, pad printing, flexography, and gravure printing. As described above, the casting/drying process can be repeated to build up the thickness of the precursor film.

Alternatively, the precursor film can be formed as a stack of layers on the layer 404 of conductive material, each layer containing at least one of the components of the precursor layer. See, for example, U.S. Pat. No. 8,426,241 issued to Ahmed et al., entitled “Structure and Method of Fabricating a CZTS Photovoltaic Device by Electrodeposition” (hereinafter “U.S. Pat. No. 8,426,241”), the contents of which are incorporated by reference as if fully set forth herein. By way of example only, the stack may include a layer containing Cu, a layer containing Zn, a layer containing Sn, and a layer containing S/Se. Alternatively, the layers may contain any of the binary, ternary, or quaternary metal chalcogenides provided above.

Since interfusion of the components will occur during the anneal, the ordering of the layers in the stack might not be important. However, it may be desirable to place the layers containing the least volatile elements (e.g., Cu and Zn) up top in the stack to help suppress evaporation of the more volatile elements (e.g., Sn, S, and Se) during the anneal. A thickness of each of the layers may be tailored based on the desired amount of its components in the precursor film. For instance, making the Cu-containing layer twice as thick as the Zn-containing layer will provide for twice as much Cu in the precursor layer as Zn. The layers of the precursor film may be deposited onto the substrate 402 using any suitable deposition process including, but not limited to, solution coating, evaporation, sputtering, and electrochemical deposition (see, for example, U.S. Pat. No. 8,426,241).

The substrate/precursor film is then placed in the conditioned chamber and annealed under conditions sufficient to form the kesterite absorber 502. According to an exemplary embodiment, the conditions include a temperature of from about 570° C. to about 650° C., and ranges therebetween, for a duration of from about 5 minutes to about 15 minutes, and ranges therebetween. Optionally, as provided above, a source of S and/or Se may be provided during the anneal to supply these components for the kesterite absorber 502 and/or to compensate for their evaporative loss from the precursor film. By way of example only, suitable techniques for providing S and Se during CZTS/Se fabrication are described in U.S. Patent Application Publication Number 2012/0100663 by Bojarczuk et al., entitled “Fabrication of CuZnSn(S,Se) Thin Film Solar Cell with Valve Controlled S and Se,” the contents of which are incorporated by reference as if fully set forth herein.

By processing the precursor film in the conditioned chamber, a high quality kesterite absorber material is produced. In fact, the present techniques can be used to consistently produce solar cells with a power conversion efficiency of greater than 12% (e.g., 12.6% power conversion efficiency). Solar cell efficiencies at this level have not been achievable using conventional processes. Without being bound by any particular theory, it is thought that by conditioning the chamber the volatile species reach a narrow window of dynamic equilibrium with the elements in the film, which seems to stabilize the favorable formation of CZTSSe films with much lower defect densities and thus improves the power conversion efficiency of the film.

Advantageously, as provided above, the same conditioned chamber can be used to process a multitude of samples before cleaning and reconditioning (as per methodology 100 of FIG. 1) needs to be performed again. For instance, testing has shown that the same conditioned chamber can be used for high volume processing of samples for a period of greater than 6 months before cleaning and reconditioning is needed.

Next, as shown in FIG. 6, an n-type semiconductor layer 602 is then formed on the kesterite absorber 502. According to an exemplary embodiment, the n-type semiconductor layer 602 includes zinc sulfide (ZnS), cadmium sulfide (CdS), indium sulfide (InS), oxides and/or selenides thereof. The n-type semiconductor layer 602 may be formed on the kesterite absorber 502 using for example vacuum evaporation, chemical bath deposition, electrochemical deposition, atomic layer deposition (ALD), or successive ionic layer adsorption and reaction (SILAR).

An antireflection coating 604 is then formed on the n-type semiconductor layer 602. Magnesium fluoride (MgF₂) is a suitable material for reducing reflection of light off of the surface. It can be deposited by evaporation or sputtering.

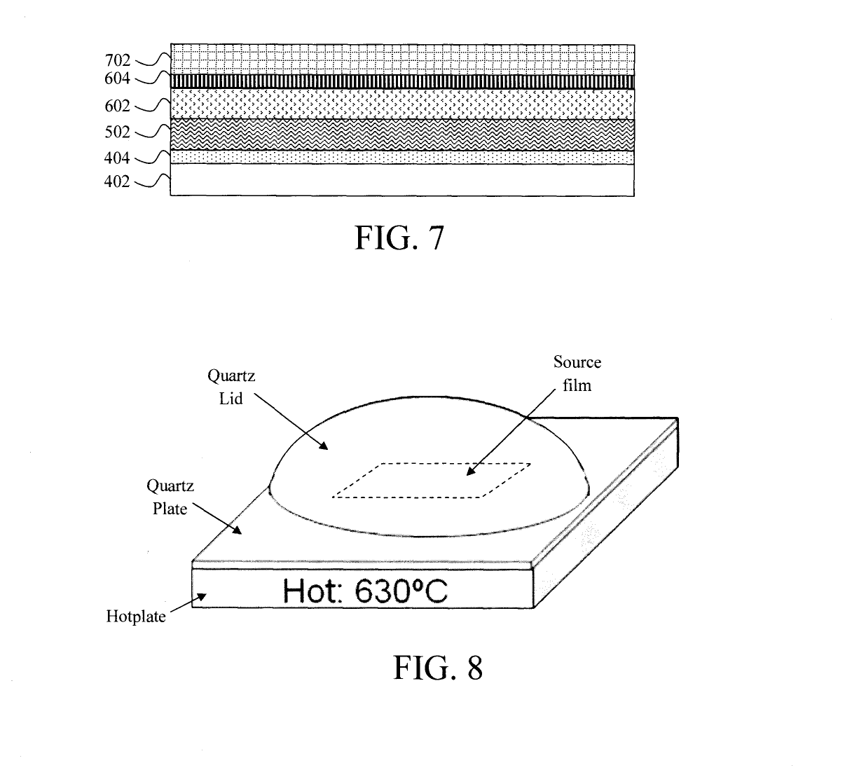

As shown in FIG. 7, a top electrode 702 is then formed on the antireflection coating 604. According to an exemplary embodiment, the top electrode 702 is formed from a transparent, electrically conductive material such as a transparent conductive oxide (TCO), e.g., indium-tin-oxide (ITO) and/or indium-zinc-oxide (IZO). The process for forming a top contact from these TCO materials is known in the art, and thus not described in further detail herein.

The present techniques are now further illustrated by way of reference to the following non-limiting example. In this example, the above-described process is used to condition a quartz lid. See FIG. 8. Once conditioned, the quartz lid can be placed over samples during annealing to improve the clarity of the resulting kesterite film.

In the example shown in FIG. 8, a quartz lid was placed on a (e.g., Cu) hotplate. Once the hotplate reached a temperature of about 630° C., the quartz lid was lifted and a quartz plate with a source film (see, for example, methodology 200 of FIG. 2) was placed on the hotplate underneath the quartz lid (i.e., with the source film facing the inner side of the quartz lid). The quartz lid was immediately put back in place over the source film. In this example, the source film contained Sn, S, and Se. Once placed on the hotplate, the Sn, S, and Se evaporated from the source film to deposit a coating (of Sn, S, and Se) on the quartz lid. This annealing of the source film on the hotplate was carried out for a duration of from about 10 minutes to about 15 minutes, and ranges therebetween. The conditioning process was repeated from 1-10 times, and ranges therebetween, to fully condition the quartz lid.

Although illustrative embodiments of the present invention have been described herein, it is to be understood that the invention is not limited to those precise embodiments, and that various other changes and modifications may be made by one skilled in the art without departing from the scope of the invention.

What is claimed is:

1. A method of conditioning an annealing chamber for forming a kesterite film, the method comprising the step of:
coating one or more inner surfaces of the annealing chamber with a film containing Sn and at least one of S and Se.

2. The method of claim 1, further comprising the steps of:
placing a source film on a substrate within the annealing chamber, wherein the source film comprises Sn and at least one of S and Se; and
heating the source film within the annealing chamber to create a vapor comprising Sn and at least one of S and Se; and
cooling the annealing chamber to condense components from the vapor on the one or more inner surfaces of the annealing chamber to form the film containing Sn and at least one of S and Se.

3. The method of claim 2, wherein the source film further comprises Cu and Zn.

4. The method of claim 2, wherein the step of heating the source film further comprises the step of:
increasing a temperature in the annealing chamber until the temperature in the annealing chamber is from about 570° C. to about 650° C., and ranges therebetween.

5. The method of claim 4, wherein the temperature in the annealing chamber is increased at a ramping rate of less than 120° C. per minute.

6. The method of claim 2, further comprising the steps of:
preparing an ink comprising Sn and at least one of S and Se dissolved or dispersed in a liquid medium;
depositing the ink onto the substrate; and
drying the ink to form the source film on the substrate.

7. The method of claim 6, wherein the liquid medium comprises hydrazine or a hydrazine-water mixture.

8. The method of claim 6, wherein the ink is dried at a temperature of from about 50° C. to about 150° C., and ranges therebetween.

9. The method of claim 2, further comprising the step of:
repeating the heating and cooling steps n times, wherein n=1-10.

10. The method of claim 1, further comprising the steps of:
preparing an ink comprising Sn and at least one of S and Se dissolved or dispersed in a liquid medium;
depositing the ink onto the one or more inner surfaces of the annealing chamber; and
drying the ink to form the film containing Sn and at least one of S and Se on the one or more inner surfaces of the annealing chamber.

11. The method of claim 10, wherein the ink is deposited onto the one or more inner surfaces of the annealing chamber using spin coating, dip coating, doctor blading, curtain coating, slide coating, spraying, slit casting, meniscus coating, screen printing, ink jet printing, pad printing, flexography, or gravure printing.

12. A method for forming a kesterite film, the method comprising the steps of:
coating one or more inner surfaces of an annealing chamber with a film containing Sn and at least one of S and Se; and
heating a precursor film on a substrate within the annealing chamber to form the kesterite film on the substrate.

13. The method of claim 12, wherein the coating step comprises the steps of:
placing a source film within the annealing chamber, wherein the source film comprises Sn and at least one of S and Se; and
heating the source film within the annealing chamber to create a vapor comprising Sn and at least one of S and Se; and
cooling the annealing chamber to condense components from the vapor on the one or more inner surfaces of the annealing chamber to form the film containing Sn and at least one of S and Se.

14. The method of claim 12, wherein the coating step comprises the steps of:
preparing an ink comprising Sn and at least one of S and Se dissolved or dispersed in a liquid medium;
depositing the ink onto the one or more inner surfaces of the annealing chamber; and
drying the ink to form the film containing Sn and at least one of S and Se on the one or more inner surfaces of the annealing chamber.

15. The method of claim 12, wherein the precursor film comprises Cu, Zn, Sn, and at least one of S and Se.

16. A method for forming a solar cell, the method comprising the steps of:
coating one or more inner surfaces of an annealing chamber with a film containing Sn and at least one of S and Se;
heating a precursor film on a substrate within the annealing chamber to form a kesterite absorber on the substrate;
forming an n-type semiconductor on the kesterite absorber; and
forming a top electrode on the n-type semiconductor.

17. The method of claim 16, wherein the coating step comprises the steps of:
placing a source film within the annealing chamber, wherein the source film comprises Sn and at least one of S and Se;
heating the source film within the annealing chamber to create a vapor comprising Sn and at least one of S and Se; and
cooling the annealing chamber to condense components from the vapor on the one or more inner surfaces of the annealing chamber to form the film containing Sn and at least one of S and Se.

18. The method of claim 16, wherein the coating step comprises the steps of:
preparing an ink comprising Sn and at least one of S and Se dissolved or dispersed in a liquid medium;
depositing the ink onto the one or more inner surfaces of the annealing chamber; and
drying the ink to form the film containing Sn and at least one of S and Se on the one or more inner surfaces of the annealing chamber.

19. A solar cell, comprising:
a substrate;
a bottom electrode on the substrate;
a kesterite absorber on the bottom electrode, wherein the kesterite absorber comprises a kesterite film formed according to the method of claim 12;
an n-type semiconductor on the kesterite absorber;
an antireflection coating on the n-type semiconductor; and
a top electrode on the antireflection coating.

20. The solar cell of claim 19, wherein the solar cell has a power conversion efficiency of greater than 12%.
